(19) United States
(12) Patent Application Publication
(10) Pub. No.: US 2017/0133083 A1
(43) Pub. Date: May 11, 2017

(54) MEMORY DEVICES AND SYSTEMS INCORPORATION BETWEEN-DIMM BUFFERING TO INCREASE CAPACITY AND BANDWIDTH

(71) Applicant: Intel Corporation, Santa Clara, CA (US)

(72) Inventors: Qin Li, Folsom, CA (US); Min Wang, Santa Clara, CA (US)

(73) Assignee: Intel Corporation, Santa Clara, CA (US)

(21) Appl. No.: 14/935,291

(22) Filed: Nov. 6, 2015

(51) Int. Cl. G11C 11/4093

(52) U.S. Cl. CPC G11C 11/4093

(57) ABSTRACT

High capacity, high bandwidth memory devices and systems having on-board memory buffering are disclosed and described.

### BACKGROUND

Computer devices and systems have become integral to the lives of many, and include all kinds of uses from social media to intensive computational data analysis. Such devices and systems can include tablets, laptops, desktop computers, network servers, and the like. Memory subsystems play an important role in the implementation of such devices and systems, and are one of the key factors affecting performance.

One type of volatile memory used in many computer devices and systems is synchronous dynamic random access memory (SDRAM), which is basically DRAM with a synchronous interface that is synchronized with the system bus. Double data rate (DDR) is an interface specification that allows a computer bus to operate on both the rising and falling edges of the system clock signal, and thus DDR SDRAM is SDRAM that can operate at DDR speeds. Several advancements in DDR have resulted in various related interface specifications, such as DDR2, DDR3, DDR4, and the like.

### BRIEF DESCRIPTION OF THE DRAWINGS

FIG. 1a is a schematic top-down view of a computing memory system in accordance with an embodiment;

FIG. 1b is a schematic side view of a computing memory system in accordance with an embodiment;

FIG. 2 is a graphical representation of data in accordance with an embodiment;

FIG. 3 is a graphical representation of data in accordance with an embodiment;

FIG. 4a is a schematic top-down view of a computing memory system in accordance with an embodiment;

FIG. 4b is a schematic side view of a computing memory system in accordance with an embodiment;

FIG. 5 is a graphical representation of data in accordance with an embodiment;

FIG. 6 is a graphical representation of data in accordance with an embodiment; and

FIG. 7 is a schematic view of a computing system in accordance with an invention embodiment.

### DESCRIPTION OF EMBODIMENTS

Although the following detailed description contains many specifics for the purpose of illustration, a person of ordinary skill in the art will appreciate that many variations and alterations to the following details can be made and are considered to be included herein.

Accordingly, the following embodiments are set forth without any loss of generality to, and without imposing limitations upon, any claims set forth. It is also to be understood that the terminology used herein is for the purpose of describing particular embodiments only, and is not intended to be limiting. Unless defined otherwise, all technical and scientific terms used herein have the same meaning as commonly understood by one of ordinary skill in the art to which this disclosure belongs.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the compositions nature or characteristics would be permissible if present under the “consisting essentially of” language, even though not expressly recited in a list of items following such terminology. When using an open ended term in this specification, like “comprising” or “including,” it is understood that direct support should be afforded also to “consisting essentially of” language as well as “consisting of” language as if stated explicitly and vice versa.

“The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

As used herein, “enhanced,” “improved,” “performance-enhanced,” “upgraded,” and the like, when used in connection with the description of a device or process, refers to a characteristic of the device or process that provides measurably better form or function as compared to previously known devices or processes. This applies both to the form and function of individual components in a device or process, as well as to such devices or processes as a whole.

As used herein, “coupled” refers to a relationship of physical connection or attachment between one item and another item, and includes relationships of either direct or indirect connection or attachment. Any number of items can be coupled, such as materials, components, structures, layers, devices, objects, etc.

As used herein, “directly coupled” refers to a relationship of physical connection or attachment between one item and another item where the items have at least one point of direct physical contact or otherwise touch one another. For example, when one layer of material is deposited on or against another layer of material, the layers can be said to be directly coupled.

As used herein, “associated with” refers to a relationship between one item, property, or event and another item, property, or event. For example, such a relationship can be a relationship of communication. Additionally, such a relationship can be a relationship of coupling, including direct, indirect, electrical, or physical coupling. Furthermore, such a relationship can be a relationship of timing.

Objects or structures described herein as being “adjacent to” each other may be in physical contact with each other, in close proximity to each other, or in the same general region or area as each other, as appropriate for the context in which the phrase is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. However, it is to be understood that even when the term “about” is used in the present specification in connection with a specific numerical value, that support for the exact numerical value recited apart from the “about” terminology is also provided.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

### Example Embodiments

An initial overview of technology embodiments is provided below and specific technology embodiments are then described in further detail. This initial summary is intended to aid readers in understanding the technology more quickly, but is not intended to identify key or essential technological features, nor is it intended to limit the scope of the claimed subject matter.

Among other metrics, capacity and bandwidth are two parameters that affect the performance of a memory system or subsystem. While high memory bandwidth can improve the performance of many computing platforms, a large memory capacity can also lead to beneficial improvements, particularly in applications such as datacenter and high performance computing (HPC) applications, for example, in-memory databases, scientific computing, and the like.

For traditional double data rate (DDR) memory architecture systems such as DDR3 or DDR4, memory capacity and memory bandwidth often represent competing parameters. In many cases, as a greater number of DIMMs are connected in a memory channel, data transfer rate must be reduced to accommodate the increased bus loading. Similarly, as data transfer rate increases, a fewer number of DIMMs can be connected in a memory channel because of the need to reduce electrical loading. Efforts to fulfill the needs of both memory bandwidth and capacity have included fully Buffered DIMM (FB-DIMM), load reduced DIMM (LR-DIMM), shortening the motherboard length through buffer-on-motherboard designs, as well as increasing CPU memory channels, and the like. Such efforts have generally not provided optimal solutions to the bandwidth/capacity problem.

In some aspects, invention embodiments allow memory capacity to be increased without sacrificing bandwidth, and without adding additional memory channels. For example, a 3 DIMMS per channel (DPC) memory system architecture can run at much higher speed bins, such as up to DDR4 or more. Furthermore, various embodiments allow for single memory channel scaling, thus allowing additional DIMMS to be added to a memory channel. Capacity and bandwidth can thus be decoupled, at least to some extent, to provide greatly increased memory performance.

In some aspects, embodiments achieve memory performance increases through the introduction of a buffer element, such as a memory buffer, into a memory channel of a given memory architecture. Generally, one or more memory buffers can be added to a circuit board and integrated into a memory channel. In the case of a motherboard, for example, the memory buffers can be electrically coupled to data lines of a memory channel at various points between the central processing unit (CPU) and any of the DIMM connectors, depending on the system architecture. The number of buffer elements, the arrangement of the buffers, as well as various other aspects of the memory architecture can vary depending on the design of the memory system or subsystem, the use for which the system is designed, cost, various manufacturing considerations, and the like. Any such design variation is considered to be within the present scope.

In some cases, memory buffers can be added to a memory channel on a motherboard having a 3 DIMMS per channel (3 DPC) architecture. The addition of such buffers can allow the memory system to effectively function as a 2 DIMMS per channel (2 DPC) architecture system from an electrical signaling point of view and as a 3 DPC architecture system from a memory capacity point of view. In other words, the buffered system has the high capacity of a 3 DPC system and the high bandwidth of a 2 DPC system.

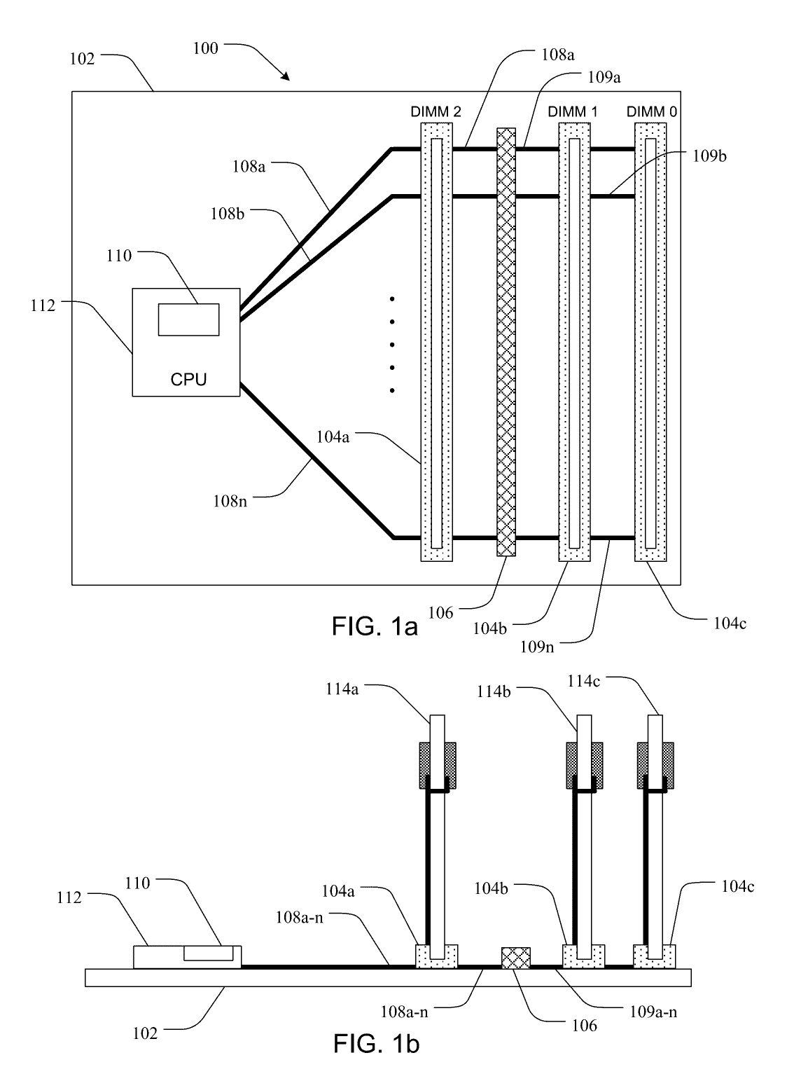

One example of a buffered computing system is shown in FIGS. 1a-b. The high capacity, high bandwidth memory system 100 can include a motherboard substrate 102, three DIMM connectors 104a-c coupled to the motherboard substrate 102, a memory buffer 106 coupled to the motherboard substrate 102 and positioned between two of the three DIMM connectors 104a-b, and data lines 108a-n on the motherboard substrate 102. The data lines 108a-n electrically couple the memory buffer 106 to the DIMM connector 104a and memory controller 110. The data lines 109a-n electrically couple the memory buffer 106 to the two DIMM connectors 104b and 104c.

The system 100 can further include a memory controller 110 coupled to the motherboard substrate 102 and electrically coupled to the DIMM connector 104a and memory buffer 106 via the data lines 108a-n. The memory controller 110 manages various memory functions and data flow to and from the DIMMs coupled to the DIMM connectors 104a-c. The memory controller 110 can be a distinct controller chip, or it can be integrated into another chip or it can be located on the same die as another chip. As one example, the memory controller chip can be an integral part of a microprocessor. The memory controller 110 can be coupled to the motherboard substrate 102 via a soldered connection, a socketed connection, integration with a separate chip, or any other known technique. In FIGS. 1a-b, the memory controller 110 is shown as an integrated component of the central processing unit (CPU) 112.

The system 100 additionally can include a processor or microprocessor, such as a CPU 112. The CPU 112 can be coupled to the motherboard substrate 102 by any useful mechanism, including via a CPU socket, soldering, and the like. The CPU 112 (and/or CPU socket) is electrically coupled to the data lines 108a-n, which generally extend to the DIMM connector 104a. DIMMs 114a-c are shown coupled to the DIMM connectors 104a-c in FIG. 1b. The DIMM connectors 104a-c are arranged in a parallel sequence in relation to one another, with a primary DIMM connector 104a being positioned closer to the memory controller 110 compared to remaining DIMM connectors 104b and 104c of the three DIMM connectors 104a-c. The memory buffer 106 is positioned between the primary DIMM connector 104a and the nearest of the remaining DIMM connectors 104b in the parallel sequence of DIMM connectors 104a-c. The data lines 109a-n from the remaining DIMM connectors 104b and 104c connect to the memory buffer 106. The DIMM connectors can be any type or configuration of DIMM connector that is compatible with a DDR2, DDR3, DDR4, or other DDR system. In one example, the DIMM connectors can be configured to receive DDR4 synchronous dynamic random-access memory (SDRAM) DIMMs. As one non-limiting example, a DIMM connector can comply with a DDR4 288 Pin U/R/LR DIMM Connector Performance Standard.

The memory buffer 106 can be a single memory buffer chip or a plurality of memory buffer chips. In one example, a plurality of memory buffers can include from 2 to 12 memory buffer chips. In a further example, a plurality of memory buffers is 9 memory buffer chips. The number of memory buffer chips can be flexible and provide various advantages for a given configuration. Any number of memory buffer chips can be utilized in a given design. In one example for a regular error-correcting code (ECC) memory channel with 9 byte lanes, 9 memory buffer chips can be used as the memory buffer, with each memory buffer chip covering a byte lane.

In some cases, the memory buffer may buffer all signal groups, such as the data (DQ), strobe (DQS), and Command/Address/Control (CMD/ADDR/CTL) signals. In other cases, the memory buffer may only buffer the DQ and DQS signals. One rationale for such buffering of data signals only is that CMD/ADDR/CTL signaling is often not on the critical path with Register-DIMM (R-DIMM) being used in many server applications.

With the added memory buffers, the pre-buffer topology is a topology that is better than typical 2 DPC topology. This is due at least in part to a single load imposed on the buffer chip branch as opposed to 2 loads imposed on a regular dual rank R-DIMM, as well as a shorter trace length from the primary DIMM connector (DIMM2; 104a) to the memory buffer 106. By contrast, typical 2 DPC topology includes a DIMM2 connector to DIMM1 DRAM devices which consists of a short length on motherboard substrate, DIMM connector, and DIMM trace length. Additionally, the post-buffer topology is a topology better than the typical 2 DPC topology, due to a shorter motherboard main branch length (e.g., 0.53″ versus 4″-5″) and a shorter buffer package length (e.g., 6 mm for the buffer chip vs. 45 mm to a CPU).

The bandwidth of a 3 DPC architecture can thus be enhanced in many cases to a level that is equal or greater than a 2 DPC architecture. In one example, the enhanced bandwidth can be from 15 GB/s to 20 GB/s using 9 memory buffers. In another example, the enhanced bandwidth can be from 15 GB/s to 22 GB/s using 9 memory buffers. The increase in bandwidth without a capacity drop can thus facilitate higher system speeds compared to a system having a traditional or native 3 DPC architecture. In one example, the data speed for such a system, assuming 9 memory buffers, is from 1600 Mbps to 2667 Mbps. In another example, the data speed for such a system, again assuming 9 memory buffers, is from 1600 Mbps to 2400 Mbps.

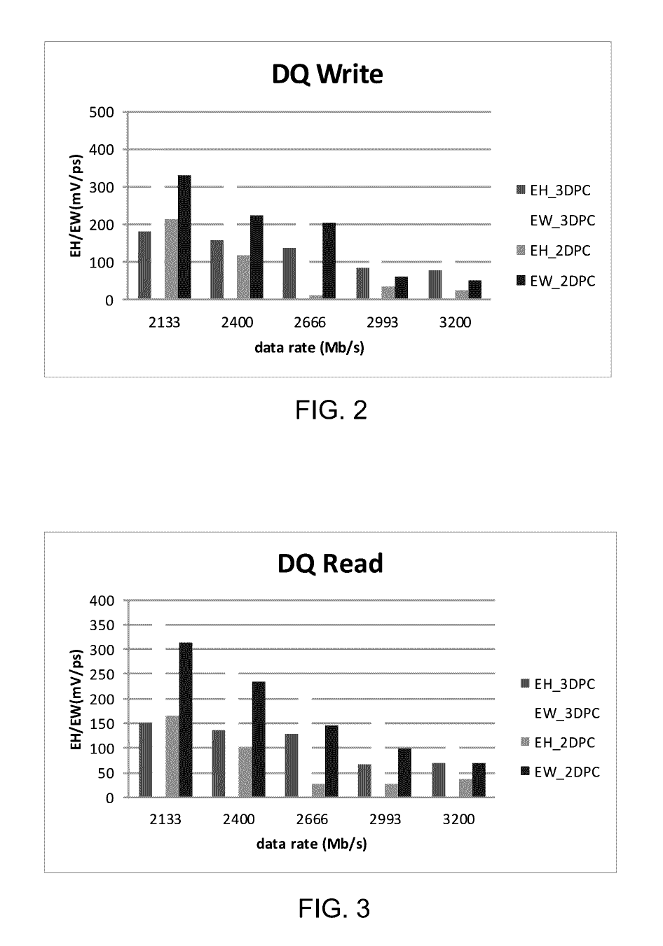

FIG. 2 shows exemplary data of a comparison between the worse-case eye height (EH) and eye width (EW) which is simulated based on the presently disclosed technology (marked “3 DPC”) and traditional 2 DPC architecture data across all the DIMMs for the Write direction. As can be seen, the 3 DPC case has consistently better margins than the 2 DPC across higher speed bins. For example, at 3200 Mbps, buffered 3 DPC is ˜60 mV and ˜0.21 UI better than the traditional 2 DPC case on eye margins. FIG. 3 shows a similar comparison for the Read direction, with similar results.

As other examples of non-limiting implementations of the present technology, a capacity scalable architecture capable of increasing the number of DPC can be realized using cascaded on-board memory buffers. By adding distributed memory buffers onto a circuit board (e.g., a motherboard) for each DIMM connected in a memory channel, the number of DIMMS capable of being connected to the memory channel can be increased. A 2 DPC architecture, for example, can thus support 3 or more DIMMs in a single memory channel. Such a system has substantially better electrical performance compared to the traditional 2 DPC architecture. The system will therefore have the high capacity of a scalable N-DPC solution, while achieving a higher bandwidth than the traditional 2 DPC.

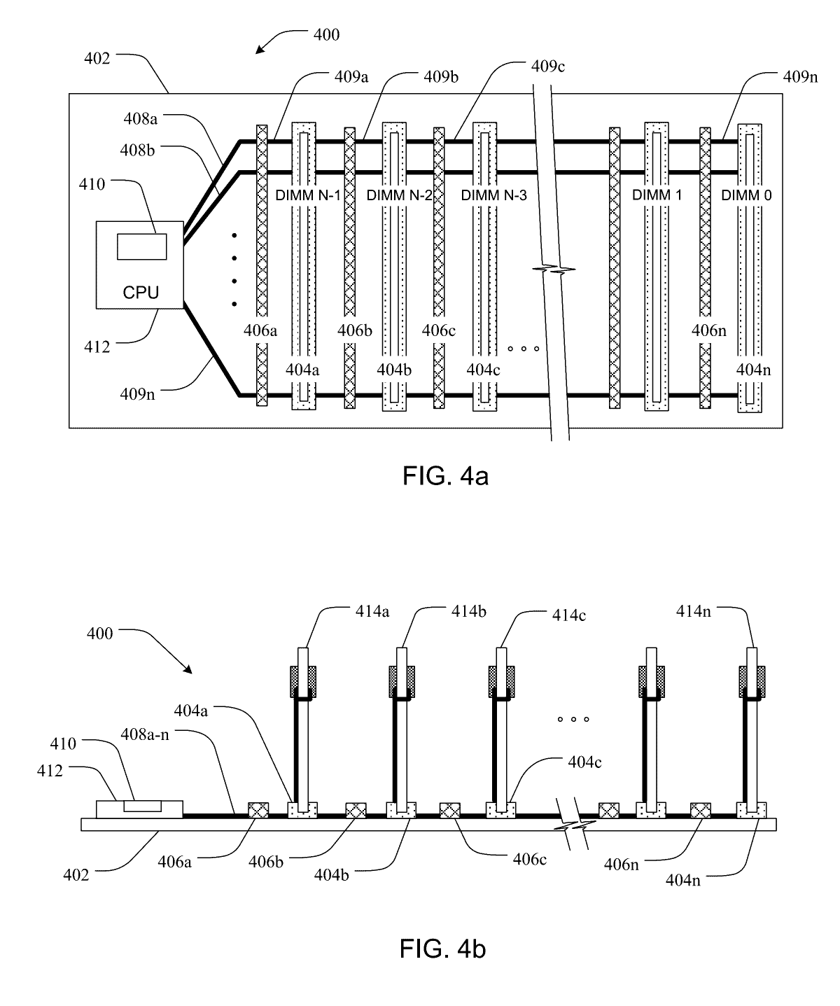

One example of a system having a scalable memory architecture is shown in FIGS. 4a-b, where FIG. 4a is a top-down view and FIG. 4b is a side view, but including DIMMs coupled to the DIMM connectors that are not shown in FIG. 4a. The system 400 can include a motherboard substrate 402 upon which a plurality of series of DIMM connectors 404a, 404b, 404c, . . . 404n are coupled. A series of memory buffer sets 406a, 406b, 406c, . . . 406n is coupled to the motherboard substrate 402. A memory buffer 406a-n, therefore, is associated with each DIMM connector 404a-n in a memory channel. In FIGS. 4a-b, each DIMM connector 404a-n has an associated memory buffer 406a-n positioned adjacent a side of the DIMM connector nearest to the memory controller 410. Data lines 409a-n are positioned on, and coupled to, the motherboard substrate 402, and electrically couple the memory buffers 406a-n to the DIMM connectors 404a-n and to the next adjacent memory buffer 406a-n. In other words, data line 409a electrically couples memory buffers 406a and 406b to DIMM connector 404a, data line 409b electrically couples memory buffers 406b and 406c to DIMM connector 404b, and so on.

System 400 can further include a memory controller 410 coupled to the motherboard substrate 402, and electrically coupled to the memory buffer 406a via the data lines 408a-n. The memory controller 410 manages various memory functions and data flow to and from the DIMMs coupled to the DIMM connectors 404a-n. Memory buffers serve as a repeater to re-transmit data received from the memory controller and DIMM to the next neighboring DIMM and memory buffer. The memory controller 410 can be a distinct controller chip, or it can be integrated into another chip or be located on the same die as another chip. As one example, the controller chip can be an integral part of a microprocessor such as a CPU. The memory controller can be coupled to the motherboard substrate via a soldered connection, a socketed connection, integration with a separate chip, or any other known technique.

The system 400 additionally can include a microprocessor, such as a CPU 412. The CPU 412 can be coupled to the motherboard substrate 402 by any useful mechanism, including via a CPU socket, soldering, and the like. The CPU 412 is (and/or CPU socket) electrically coupled to the data lines 408a-n, which generally connects to the memory controller 410. DIMMs 414a-n are shown coupled to the DIMM connectors 404a-n in FIG. 4b. The DIMM connectors 404a-n are arranged in a parallel sequence or series in relation to one another, with the memory buffers 406a-n positioned adjacent thereto as has been described. The DIMM connectors can be any type or configuration of DIMM connector useful for a given memory architecture design. In one example, the DIMM connectors can be configured to receive DDR2, DDR3, DDR4, or greater synchronous dynamic random-access memory (SDRAM) DIMM. In one example, the DIMM connectors can be configured to receive DDR4 synchronous dynamic random-access memory (SDRAM) DIMM. For example, DIMM connects can comply with a DDR4 288 Pin U/R/LR DIMM Connector Performance Standard.

In general, the memory buffer functions as an intermediary between the memory controller and the DIMM associated with that memory buffer. When the memory controller drives data to the DRAM of DIMM memory for a write operation, the memory buffer receives and re-drives the data to one or more DIMMs downstream from the memory buffer. The memory buffers essentially isolate the DIMMs from the memory controller, thus reducing the electrical loads on the interfaces. When a DIMM drives data to the memory controller for a read operation, the memory buffer functions in a similar manner, but in the opposite direction. Thus, a memory buffer picks up data from the DIMM and transmits it to the memory controller. The resulting reduction of the electrical loading allows the memory system to operate at higher speeds than would otherwise be possible.

The memory buffer 406a-n can be a single memory buffer chip, or the memory buffer 406a-n can be a plurality of memory buffer chips. In one example, a plurality of memory buffer chips can include from 2 to 12 memory buffer chips. In a further example, a plurality of memory buffers is 9 memory buffer chips. The number of memory buffer chips in each memory channel can be flexible, and as such, any number of memory buffer chips can be utilized in a given design in order to obtain desired advantages or avoid undesirable disadvantages. In one example for a regular ECC memory channel, 9 memory buffer chips can be used, with each memory buffer chip covering a byte lane. In some cases, the memory buffer chips may buffer all signal groups, DQ/DQS, CMD/ADDR, and CTL. In other cases, the memory buffer chips may buffer only the DQ/DQS. Better scalability to a higher number of DIMMS, however, can be achieved through the buffering of all signal groups.

With the inserted memory buffers, the operation speed of each segment of the signaling path can be pushed much higher. Despite the fact that there are still 3 loads (two loads from the dual rank DIMM and the other one from the buffer), the small length of the interconnect for data lines 409a-n helps to significantly reduce crosstalk and loss, and therefore the buffered scheme outperforms a traditional 2 DPC topology considerably.

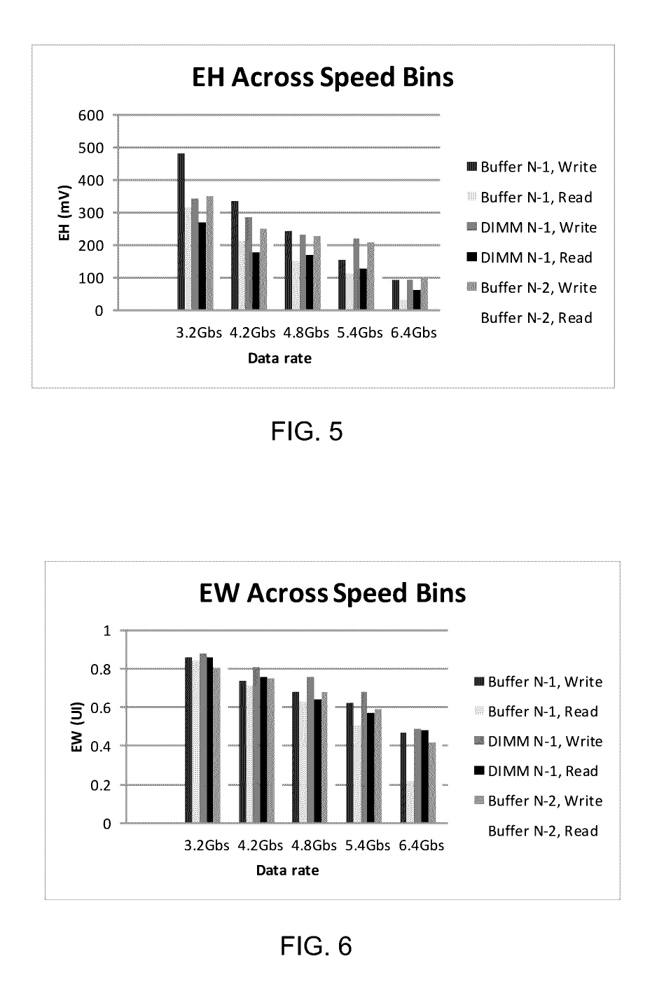

For example, with a traditional 2 DPC approach, R-DIMM can achieve approximately 2 DPC 2400 Mbps and 3 DPC 1333 Mbps, while LR-DIMM can achieve 2 DPC 2993 Mbps and 3 DPC 1600 Mbps. It is commonly believed to not be possible to enable 4.2 Gbps or beyond for traditional 2 DPC and traditional 3 DPC architectures. Performance-wise, FIGS. 5-6 show simulated eye height (EH) and eye width (EW), respectively, for memory buffer 406a, memory buffer 406b, and DIMM N−1, which is plugged onto DIMM connector 404a, for both Write and Read directions including equalization optimization. The number of taps and type of equalization used at each simulation are listed in Table 1. At 5.4 Gbps, the worst-case EH and EW are observed when memory buffer 406a is sending a signal back to the memory controller with the value of 114 mV and 0.51 UI. This could be further improved with the host Cpad reduction using advanced process technologies. In addition, only a single type of equalization was assumed for each simulation. With the combination of multiple types and taps of equalization optimization, e.g., transmitter and receiver equalization together, 6.4 Gbs speeds can also be achievable with further optimization. It is also worth mentioning that equalization may not be needed at lower speed bins such as 3.2 Gbps, depending on the circuit voltage and timing requirements. The results in FIGS. 5-6 show that multiple DIMMs per channel can achieve data speeds of 5.4 Gb/s, while the traditional memory implementations can only achieve 1.6 Gb/s for 3 DPC.

TABLE 1
EQ types and taps used in the simulations.

| Buffer N-1 | | DIMM N-l | | Buffer N-2 | |
|---|---|---|---|---|---|
| Write | Read | Write | Read | Write | Read |
| 2 tap TXLE | 1 tap DFE | no EQ | 1 tap DFE | 1 tap DFE | 1 tap DFE |

Additionally, in some examples, such a system can be used to partially populate DIMM slots depending on the platform capacity requirement without sacrificing bandwidth. Since the DIMM slots are separated by the memory buffers, the implementation of partially populated DIMMs is apparent, and is accomplished by filling DIMM slots close to the CPU first, while maintaining the same data rate. Inactive memory buffers, except for one that is providing termination, can be turned off to save platform power.

As a general point, any number of memory chips or memory buffer chips can be utilized in a memory buffer of for a given design. In one example for a regular error-correcting code (ECC) memory channel with 9 byte lanes, 9 memory buffer chips can be used as the memory buffer, with each memory buffer chip covering a byte lane. Thus, the 11 signals of a given byte lane can be connected to 11 inputs (or outputs) of a memory buffer chip on one side, and 11 signals in the corresponding byte lane can be connected to 11 outputs (or inputs) on the other side. If a single memory chip is used as the memory buffer for the entire data channel (or data line), then the 99 signals would be connected to 99 pins on one side of the memory buffer chip and the corresponding data line would be connected to 99 pins on the other side of the memory chip. As such, different numbers of memory buffer chips in a given memory buffer could be wired to divide up the signals in the data line in various different ways. In one aspect, for example, 11 memory buffer chips in a memory buffer could each carry 9 signals of the data line, with 9 pins used on each side of each memory chip. In another aspect, 5 memory buffer chips in a memory buffer could have 4 memory buffer chips carrying 22 signals each, with the 5^{th} chip carrying 11 signals. Accordingly, any combination of the signals of the data line can be wired to any number of memory buffer chips.

It is noted that any memory buffer chip that can be utilized as, or in, a memory buffer is considered to be within the present scope. Various memory buffer chip designs may necessitate various different wiring designs, but such would be well within the ability of those skilled in the art, once in possession of the present disclosure. Non-limiting examples of potentially useful memory buffer chips, however, can include the iDDR4DB2-GS02 dual 4-bit bidirectional data register and the iMB02-GS02B LRDIMM memory buffer, both from the Inphi® Corporation.

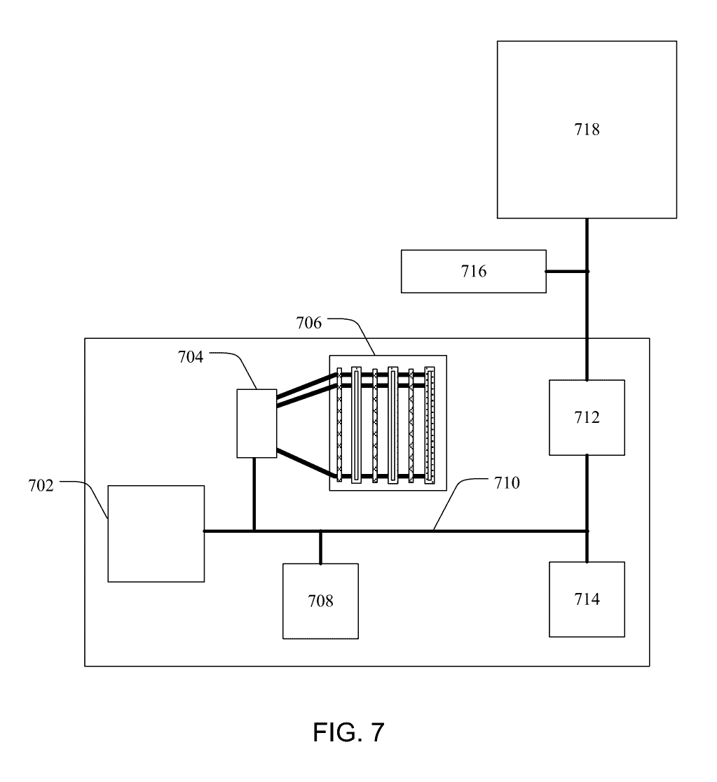

Embodiments can be utilized in any device or system having a DDR or similar memory architecture. While any type or configuration of device or computing system is contemplated to be within the present scope, non-limiting examples can include laptop computers, CPU systems, SoC systems, server systems, networking systems, storage systems, high capacity memory systems, computer systems having at least 3 DPC, or any other computational system that can benefit from a high capacity, high bandwidth memory architecture. One example of a computing system is shown in FIG. 7, which can include a processor 702 in communication with a memory controller 704 and a volatile memory subsystem 706 utilizing various memory buffers as has been described. The memory controller 704 can be a distinct controller, integrated into the processor 702, or implemented into the system by any other appropriate technique. The system can also include additional memory 708 that can include any device, combination of devices, circuitry, and the like that is capable of storing, accessing, organizing and/or retrieving data. Non-limiting examples include SANs (Storage Area Network), cloud storage networks, volatile or non-volatile RAM, phase change memory, optical media, hard-drive type media, and the like, including combinations thereof.

The system can additionally include a local communication interface 710 for connectivity between the various components of the system. For example, the local communication interface can be a local data bus and/or any related address or control busses as may be desired.

The system can also include an I/O (input/output) interface 712 for controlling the I/O functions of the system, as well as for I/O connectivity to devices outside of the system. A network interface 714 can also be included for network connectivity, either as a separate interface or as part of the I/O interface 712. The network interface 714 can control network communications both within the system and outside of the system. The network interface can include a wired interface, a wireless interface, a Bluetooth interface, optical interface, and the like, including appropriate combinations thereof. Furthermore, the system can additionally include a user interface 716, a display device 718, as well as various other components that would be beneficial for such a system.

The processor can be a single or multiple processors, and the memory can be a single or multiple memories. The local communication interface can be used as a pathway to facilitate communication between any of a single processor, multiple processors, a single memory, multiple memories, the various interfaces, and the like, in any useful combination.

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint memory device, or other byte addressable nonvolatile memory device. In one embodiment, the memory device can be or include multi-threshold level NAND flash memory, NOR flash memory, single or multi-level Phase Change Memory (PCM), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

The following examples pertain to specific embodiments and point out specific features, elements, or steps that can be used or otherwise combined in achieving such embodiments.

### Examples

The following examples pertain to specific embodiments and point out specific features, elements, or steps that can be used or otherwise combined in achieving such embodiments.

In one example there is provided a computing system, comprising:

a motherboard substrate;

a plurality of DIMM connectors coupled to the motherboard substrate;

at least one memory buffer coupled to the motherboard substrate and positioned between two of the DIMM connectors; and

data lines coupled to the motherboard substrate, the data lines electrically coupling the memory buffer to the plurality of DIMM connectors.

In one example of a computing system, the system further comprises a memory controller coupled to the motherboard substrate and electrically coupled to the DIMM connectors via the data lines.

In one example of a computing system, the memory controller is coupled to the motherboard substrate by a solder connection.

In one example of a computing system, they system further comprises a memory controller socket, wherein the memory controller is coupled to the motherboard substrate via the memory controller socket.

In one example of a computing system, the plurality of DIMM connectors are arranged in a parallel sequence in relation to one another, with a primary DIMM connector being positioned closer to the memory controller compared to remaining DIMM connectors of the plurality of DIMM connectors, and wherein the memory buffer is positioned between the primary DIMM connector and a next DIMM connector in the parallel sequence of DIMM connectors.

In one example of a computing system, the data lines from the remaining DIMM connectors pass through the memory buffer prior to contacting the primary DIMM connector.

In one example of a computing system, the at least one memory buffer comprises from 2 to 9 memory buffer chips.

In one example of a computing system, the system has a three DIMM per channel (3 DPC) architecture with a 3 DPC memory capacity and enhanced bandwidth, wherein the enhanced bandwidth is equal to or greater than a two DIMM per channel (2 DPC) architecture.

In one example of a computing system, the at least one memory buffer further comprises 9 memory buffer chips, and the enhanced bandwidth is from 15 GB/s to 22 GB/s.

In one example of a computing system, the system further comprises at least one DIMM coupled to at least one of the plurality of DIMM connectors.

In one example of a computing system, the at least one DIMM is a double data rate type 4 (DDR4) synchronous dynamic random-access memory (SDRAM) DIMM.

In one example of a computing system, the plurality of DIMM connectors comprises three DIMM connectors and are configured to accept double data rate type 4 (DDR4) DIMMs.

In one example of a computing system, the system has a three DIMM per channel (3 DPC) architecture with a 3 DPC memory capacity and enhanced bandwidth that provides a data speed from 1600 Mbps to 2667 Mbps.

In one example of a computing system, the plurality of DIMM connectors comprises three DIMM connectors and the at least one memory buffer is a single memory buffer positioned between two of the DIMM connectors.

In one example of a computing system, the plurality of DIMM connectors comprises more than three DIMM connectors and a memory buffer is associated with each DIMM connector.

In one example of a computing system, the system further comprises a central processing unit (CPU) socket coupled to the motherboard and electrically coupled to the data lines and one or more of:

a network interface communicatively coupled to the CPU,

a display communicatively coupled to the CPU, or

a battery coupled to the CPU.

In one example of a computing system, the system further comprises a CPU coupled to the CPU socket.

In one example of a computing system, the CPU comprises an integrated memory controller.

In one example there is provided, a memory device, comprising:

a memory controller;

three DIMM connectors;

data lines electrically coupling the three DIMM connectors to the memory controller; and

a memory buffer positioned between two of the three DIMM connectors and electrically coupled to the data lines.

In one example of a memory device, the three DIMM connectors are arranged in a parallel sequence in relation to one another, with a primary DIMM connector being positioned closer to the memory controller compared to remaining DIMM connectors of the three DIMM connectors, and wherein the memory buffer is positioned between the primary DIMM connector and a next DIMM connector in the parallel sequence of DIMM connectors.

In one example of a memory device, the data lines from the remaining DIMM connectors pass through the memory buffer prior to contacting the primary DIMM connector.

In one example of a memory device, the memory buffer comprises from 2 to 9 memory buffer chips.

In one example there is provided, a computing system, comprising:

a motherboard substrate;

a plurality of DIMM connectors coupled to the motherboard substrate;

a plurality of memory buffers coupled to the motherboard substrate such that a memory buffer is associated with each DIMM connector of the plurality of DIMM connectors; and

data lines coupled to the motherboard substrate electrically coupling the plurality of memory buffers to the plurality of DIMM connectors.

In one example of a computing system, the system further comprises a memory controller coupled to the motherboard substrate and electrically coupled to the DIMM connectors via the data lines.

In one example of a computing system, the memory controller is coupled to the motherboard substrate by a solder connection.

In one example of a computing system, the system further comprises a memory controller socket, wherein the memory controller is coupled to the motherboard substrate via the memory controller socket.

In one example of a computing system, the plurality of DIMM connectors is arranged in a parallel sequence, and each memory buffer is positioned on the motherboard substrate at a side of the associated DIMM connector nearest the memory controller.

In one example of a computing system, at least one of the plurality of memory buffers is positioned between each pair of adjacent DIMM connectors of the plurality of DIMM connectors, and between the memory controller and the plurality of DIMM connectors.

In one example of a computing system, the plurality of memory buffers each comprises from 2 to 9 memory buffer chips.

In one example of a computing system, the plurality of DIMM connectors includes at least 5 DIMM connectors.

In one example of a computing system, the system further comprises at least one DIMM coupled to at least one of the plurality of DIMM connectors.

In one example of a computing system, the system further comprises a central processing unit (CPU) socket coupled to the motherboard and electrically coupled to the data lines.

In one example of a computing system, the system further comprises a CPU coupled to the CPU socket.

In one example of a computing system, the CPU comprises an integrated memory controller.

In one example there is provided, a memory device, comprising:

a memory controller;

a plurality of DIMM connectors;

data lines electrically coupling the plurality of DIMM connectors to the memory controller; and

a memory buffer associated with and positioned adjacent to each DIMM connector of the plurality of DIMM connectors, wherein each memory buffer is electrically coupled to each associated DIMM connector.

In one example of a memory device, the plurality of DIMM connectors is arranged in a parallel sequence, and the memory buffer associated with each DIMM connector is positioned at a side nearest the memory controller.

In one example of a memory device, the memory buffer memory buffer comprises from 2 to 9 memory buffer chips.

In one example there is provided, a method, comprising:

providing a motherboard substrate;

coupling three DIMM connectors to the motherboard substrate;

coupling a memory buffer to the motherboard substrate positioned between two of the three DIMM connectors; and

electrically coupling the memory buffer to the three DIMM connectors using data lines.

In one example of a method, the method further comprises coupling a memory controller to the motherboard substrate and electrically coupling the memory controller to the DIMM connectors.

In one example of a method, the three DIMM connectors are arranged in a parallel sequence in relation to one another, with a primary DIMM connector being positioned closer to the memory controller compared to remaining DIMM connectors of the three DIMM connectors, and wherein the memory buffer is positioned between the primary DIMM connector and a next DIMM connector in the parallel sequence of DIMM connectors.

In one example of a method, the data lines from the remaining DIMM connectors pass through the memory buffer prior to contacting the primary DIMM connector.

In one example of a method, the memory buffer comprises from 2 to 9 memory buffer chips.

In one example of a method, the method further comprises coupling at least one DIMM to at least one of the three DIMM connectors.

In one example of a method, the at least one DIMM is a double data rate type 4 (DDR4) synchronous dynamic random-access memory (SDRAM) DIMM.

In one example of a method, the method further comprises coupling a central processing unit (CPU) socket to the motherboard and electrically coupling the CPU to the data lines.

In one example of a method, the method further comprises coupling a CPU to the CPU socket.

In one example there is provided, a method, comprising:

providing a motherboard substrate;

coupling a plurality of DIMM connectors to the motherboard substrate;

coupling a plurality of memory buffers to the motherboard substrate such that a memory buffer is associated with each DIMM connector of the plurality of DIMM connectors; and

electrically coupling the plurality of memory buffers to the plurality of DIMM connectors using data lines.

In one example of a method, the method further comprises coupling a memory controller to the motherboard substrate and electrically coupling the memory controller to the DIMM connectors via the data lines.

In one example of a method, the plurality of DIMM connectors is arranged in a parallel sequence, and each memory buffer is positioned on the motherboard substrate at a side of the associated DIMM connector nearest the memory controller.

In one example of a method, at least one of the plurality of memory buffers is positioned between each pair of adjacent DIMM connectors of the plurality of DIMM connectors, and between the memory controller and the plurality of DIMM connectors.

In one example of a method, the method further comprises coupling at least one DIMM to at least one of the plurality of DIMM connectors.

In one example of a method, the method further comprises coupling a central processing unit (CPU) socket to the motherboard and electrically coupling the CPU to the data lines.

In one example of a method, the method further comprises coupling a CPU to the CPU socket.

1. A computing system, comprising:
a motherboard substrate;
a plurality of DIMM connectors coupled to the motherboard substrate;
at least one memory buffer coupled to the motherboard substrate and communicatively coupled between two of the DIMM connectors, wherein the at least one memory buffer is configured to transmit data received from one DIMM connector to a next DIMM connector; and
data lines coupled to the motherboard substrate, the data lines electrically coupling the memory buffer to the plurality of DIMM connectors.

2. The system of claim 1, further comprising a memory controller coupled to the motherboard substrate and electrically coupled to the DIMM connectors via the data lines.

3. The system of claim 2, wherein the memory controller is coupled to the motherboard substrate by a solder connection.

4. The system of claim 2, further comprising a memory controller socket, wherein the memory controller is coupled to the motherboard substrate via the memory controller socket.

5. The system of claim 2, wherein the plurality of DIMM connectors are arranged in a parallel sequence in relation to one another, with a primary DIMM connector being positioned closer to the memory controller compared to remaining DIMM connectors of the plurality of DIMM connectors, and wherein the memory buffer is positioned between the primary DIMM connector and a next DIMM connector in the parallel sequence of DIMM connectors.

6. The system of claim 5, wherein the data lines from the remaining DIMM connectors pass through the memory buffer prior to contacting the primary DIMM connector.

7. The system of claim 1, wherein the at least one memory buffer comprises from 2 to 9 memory buffer chips.

8. The system of claim 1, wherein the system has a three DIMM per channel (3 DPC) architecture with a 3 DPC memory capacity and enhanced bandwidth, wherein the enhanced bandwidth is equal to or greater than a two DIMM per channel (2 DPC) architecture.

9. The system of claim 8, wherein the at least one memory buffer further comprises 9 memory buffer chips, and the enhanced bandwidth is from 15 GB/s to 22 GB/s.

10. The system of claim 1, further comprising at least one DIMM coupled to at least one of the plurality of DIMM connectors.

11. The system of claim 10, wherein the at least one DIMM is a double data rate type 4 (DDR4) synchronous dynamic random-access memory (SDRAM) DIMM.

12. The system of claim 1, wherein the plurality of DIMM connectors comprises three DIMM connectors and are configured to accept double data rate type 4 (DDR4) DIMMs.

13. The system of claim 1, wherein the system has a three DIMM per channel (3 DPC) architecture with a 3 DPC memory capacity and enhanced bandwidth that provides a data speed from 1600 Mbps to 2667 Mbps.

14. The system of claim 1, wherein the plurality of DIMM connectors comprises three DIMM connectors and the at least one memory buffer is a single memory buffer positioned between two of the DIMM connectors.

15. The system of claim 1, wherein the plurality of DIMM connectors comprises more than three DIMM connectors and a memory buffer is associated with each DIMM connector.

16-21. (canceled)

16. A method, comprising:
providing a motherboard substrate;
coupling a plurality of DIMM connectors to the motherboard substrate;
coupling a plurality of memory buffers to the motherboard substrate such that a memory buffer is associated with each DIMM connector of the plurality of DIMM connectors; and
electrically coupling the plurality of memory buffers to the plurality of DIMM connectors using data lines.

17. The method of claim 16, further comprising coupling a memory controller to the motherboard substrate and electrically coupling the memory controller to the DIMM connectors via the data lines.

18. The method of claim 16, wherein the plurality of DIMM connectors is arranged in a parallel sequence, and each memory buffer is positioned on the motherboard substrate at a side of the associated DIMM connector nearest the memory controller.

19. The method of claim 16, wherein at least one of the plurality of memory buffers is positioned between each pair of adjacent DIMM connectors of the plurality of DIMM connectors, and between the memory controller and the plurality of DIMM connectors.

20. The method of claim 16, further comprising coupling at least one DIMM to at least one of the plurality of DIMM connectors.

21. The method of claim 16, further comprising coupling a central processing unit (CPU) socket to the motherboard and electrically coupling the CPU to the data lines.
